(19) United States
(12) Patent Application Publication
(10) Pub. No.: US 2026/0314407 A1
(43) Pub. Date: Oct. 8, 2026

(54) POWER MODULE WITH SELECTIVE HEAT SPREADER

(71) Applicant: Microchip Technology Incorporated, Chandler, AZ (US)

(72) Inventors: Shesh Mani Pandey, Gilbert, AZ (US); Fernando Estrada, Mesa, AZ (US)

(73) Assignee: Microchip Technology Incorporated, Chandler, AZ (US)

(21) Appl. No.: 19/542,211

(22) Filed: Feb. 17, 2026

Related U.S. Application Data
(60) Provisional application No. 63/762,966, filed on Feb. 25, 2025.

(51) Int. Cl. H10W 40/25; H10W 40/00; H10W 72/00; H10W 72/50; H10W 74/01; H10W 74/10; H10W 74/47; H10W 90/00; H10W 90/10

(52) U.S. Cl. CPC H10W 40/251; H10W 40/03; H10W 40/255; H10W 72/075; H10W 72/527; H10W 72/5473; H10W 74/019; H10W 74/114; H10W 74/473; H10W 74/476; H10W 90/10; H10W 90/734; H10W 90/753; H10W 90/754

(57) ABSTRACT

A power module comprises a plurality of dies including a first die subset and a second die subset, with each subset including one or more of the dies. The second die subset is associated with a power module hotspot and has a higher operating temperature than the first die subset. A first encapsulation material is disposed on the first die subset. A second encapsulation material is disposed on the second die subset. The second encapsulation material has higher thermal conductivity than the first encapsulation material.

### CROSS-REFERENCE TO RELATED APPLICATIONS

The current patent application claims the benefit under 35 U.S.C. § 119(e) of the priority date of U.S. Provisional Application Ser. No. 63/762,966 titled “SELECTIVE HEAT SPREADER FOR POWER MODULE” and filed Feb. 25, 2025. The Provisional Application is hereby incorporated by reference, in its entirety, into the current patent application as if fully set forth herein.

### TECHNICAL FIELD

Various examples of the present disclosure relate to selective heat spreaders for power modules.

### BACKGROUND

Power modules may have a non-uniform temperature distribution during operation. The non-uniform temperature distribution may lead to power module hot spots. Power module hot spots may be associated with dies of a power module operating at higher operating temperatures than other dies of the power module. The power module hot spots can cause performance issues and degradation of the power module due to the high operating temperatures.

This background discussion is intended to provide information related to the present invention which is not necessarily prior art.

### SUMMARY OF THE INVENTION

According to various examples of the present disclosure, a power module comprises a plurality of dies including a first die subset and a second die subset, with each subset including one or more of the dies. The second die subset is associated with a power module hotspot and has a higher operating temperature than the first die subset. A first encapsulation material is disposed on the first die subset. A second encapsulation material is disposed on the second die subset. The second encapsulation material has higher thermal conductivity than the first encapsulation material.

According to various examples of the present disclosure, a method of making a power module comprises: providing a substrate; disposing a plurality of dies on the substrate with a second die subset being associated with a power module hotspot and having a higher operating temperature than a first die subset; encapsulating the first die subset with a first encapsulation material; and encapsulating the second die subset with a second encapsulation material having higher thermal conductivity than the first encapsulation material.

This summary is not intended to identify essential features of the examples, and is not intended to be used to limit the scope of the claims. These and other aspects of the present examples are described below in greater detail.

### BRIEF DESCRIPTION OF THE DRAWINGS

FIG. 1A illustrates an example power module in accordance with various examples of the present disclosure;

FIG. 1B illustrates a cross-sectional elevation view of the example power module taken along line 1B-1B of FIG. 1A in accordance with various examples of the present disclosure;

FIG. 2 illustrates an example method for making a power module in accordance with various examples of the present disclosure;

FIG. 3A illustrates an example power module manufactureed in accordance with various examples of the present disclosure;

FIG. 3B illustrates the example power module during manufacture, in which a mask has been placed in an overlying relationship with a subset of the dies of the power module, in accordance with various examples of the present disclosure;

FIG. 3C illustrates the example power module after an encapsulation material has been dispensed in an overlying relationship with a subset of the dies, which are associated with a localized hot spot, and the mask depicted in FIG. 3B has been removed, in accordance with various examples of the present disclosure; and

FIG. 3D illustrates the example power module after an encapsulation material has been dispensed over the remaining dies of the power module, in accordance with various examples of the present disclosure.

Unless otherwise indicated, the figures provided herein are meant to illustrate features of examples of this disclosure. These features are believed to be applicable in a wide variety of systems comprising one or more examples of this disclosure. As such, the figures are not meant to include all conventional features known by those of ordinary skill in the art to be required for the practice of the examples disclosed herein.

### DETAILED DESCRIPTION

In the following detailed description, reference is made to the accompanying drawings, which form a part hereof and in which are shown, by way of illustration, specific examples in which the present disclosure may be practiced. These examples are described in sufficient detail to enable a person of ordinary skill in the art to practice the present disclosure. However, other examples may be utilized, and structural, material, and process changes may be made without departing from the scope of the disclosure.

The illustrations presented herein are not meant to be actual views of any particular method, system, device, or structure, but are merely idealized representations that are employed to describe the examples of the present disclosure. The drawings presented herein are not necessarily drawn to scale. Similar structures or components in the various drawings may retain the same or similar numbering for the convenience of the reader; however, the similarity in numbering does not mean that the structures or components are necessarily identical in size, composition, configuration, or any other property.

The following description may include examples to help enable one of ordinary skill in the art to practice the disclosed examples. The use of the terms "exemplary," "by example," and "for example," means that the related description is explanatory, and though the scope of the disclosure is intended to encompass the examples and legal equivalents, the use of such terms is not intended to limit the scope of an example or this disclosure to the specified components, operations, features, functions, or the like.

Terms of relative location and direction (for example, above, below, left, right, upper, lower, vertical, lateral (or horizontal)) may be used to facilitate the present descriptions of examples with reference to the figures, but unless clearly understood or expressly identified otherwise, these terms are not meant to be limiting with regard to location, direction, or overall orientation, and may, for example, change as a result of a change in overall orientation.

It will be readily understood that the components of the examples as generally described herein and illustrated in the drawings could be arranged and designed in a wide variety of different configurations. Thus, the following description of various examples is not intended to limit the scope of the present disclosure but is merely representative of various examples.

As used herein, the term “subset” and the phrase “a respective one” may each refer to one or more members of the referenced group. In other words, according to various examples, the term “subset” and “a respective one” may encompass just a single one of the group.

In various examples, the thickness of a wire may be measured as the smallest cross-sectional dimension perpendicular to its length.

The term “electrically connected” may refer to components comprising conductor(s) such as terminals or contacts, with the conductor(s) of the respective electrically connected components being in electrical communication with one another via a pathway, the pathway typically comprising one or more conductor(s) such as metal(s) or metal alloy(s), optionally being interspersed with electronic component(s), and allowing the electrical communication via flow of electric current therebetween.

Various examples of the present disclosure relate to a power module including selective heat spreaders. The selective heat spreaders may be located at one or more power module hot spot(s). The selective heat spreaders may be configured to reduce a local temperature of the power module hot spots to maintain a temperature distribution of the power module within a threshold range during operation. Accordingly, peak junction temperatures may be reduced to mitigate thermo-mechanical stress and bond degradation. Moreover, thermal impedance may be decreased to enhance transient thermal performance.

In various examples, the power module may include a plurality of dies. The hot spot(s) may be located at one more of the dies. The selective heat spreaders may comprise an encapsulation material disposed on the die(s) associated with the hot spot(s). This configuration may improve thermal homogeneity among dies and reduce mismatch in electrical characteristics due to temperature-dependent behavior.

The power module may include a plurality of wires connected between respective ones of the dies and one or more terminals. A subset of the wires may be connected to the die(s) associated with the hot spot(s). The subset of the wires may have a greater wire thickness than remaining ones of the wires. According to certain aspects of the example power module, wires with greater wire thickness may additionally or alternatively be associated with other instances of power module hot spots (e.g., in which no dies are associated with the such hot spot). Selecting increased wire thickness at hotter interconnects may reduce losses and local self-heating, improve surge-current capability, and decrease voltage drop across critical connections. In combination with selective heat spreading, thicker wires at the hot spot dies (or elsewhere) may further flatten the thermal profile, enhance efficiency, and support higher switching frequencies or duty cycles without exceeding thermal constraints.

The power module may be utilized in high voltage applications (e.g., > 1.2 kV) and may be incorporated into a variety of different uses, such as automotive systems, deep well drilling, aircraft systems, railway systems, transportation systems, micro-electromechanical systems (MEMS), energy transmission systems, consumer devices, medical imaging devices, mass spectrometry devices, particle accelerators, data center systems, server systems, computing systems, and industrial systems, without limitation. In various examples, the power module may be utilized as a power switch, buck converter, boost converter, buck-boost converter, DC/DC converter, rectifier, inverter, flyback converter, AC/DC converter, and DC/AC converter, and the like, without limitation. In various examples, the power module may be configured to operate at high operating temperatures (e.g., > 150º C). It will be appreciated by one of ordinary skill in the art that, according to some examples, the power modules described herein may be utilized in lower voltage applications (e.g., <1.2 kV) and/or at lower operating temperatures (e.g., < 150º C) without departing from the spirit of the present disclosure.

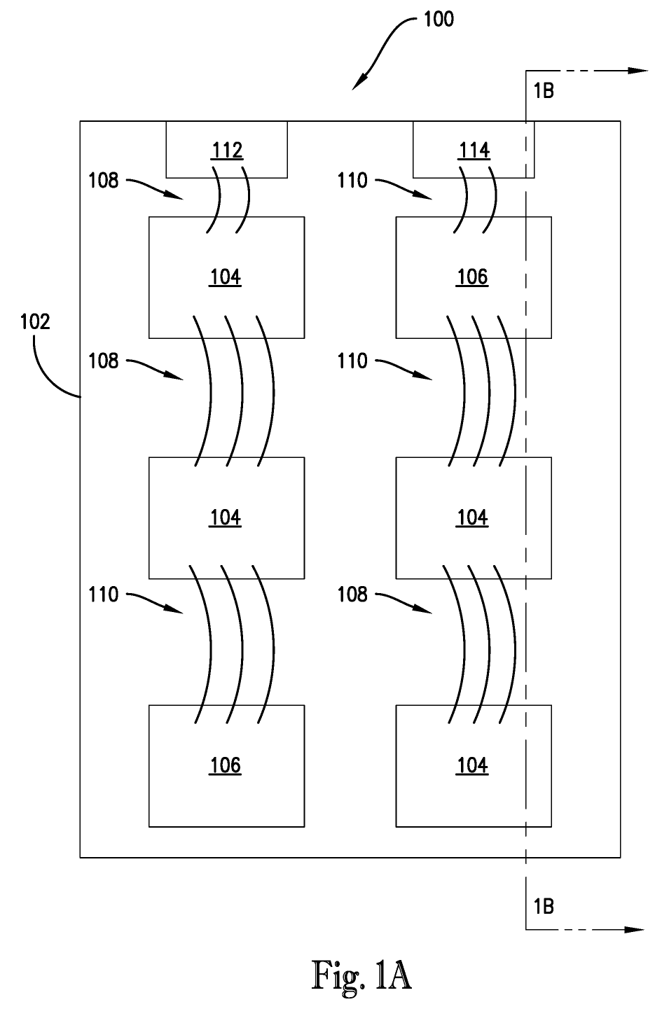

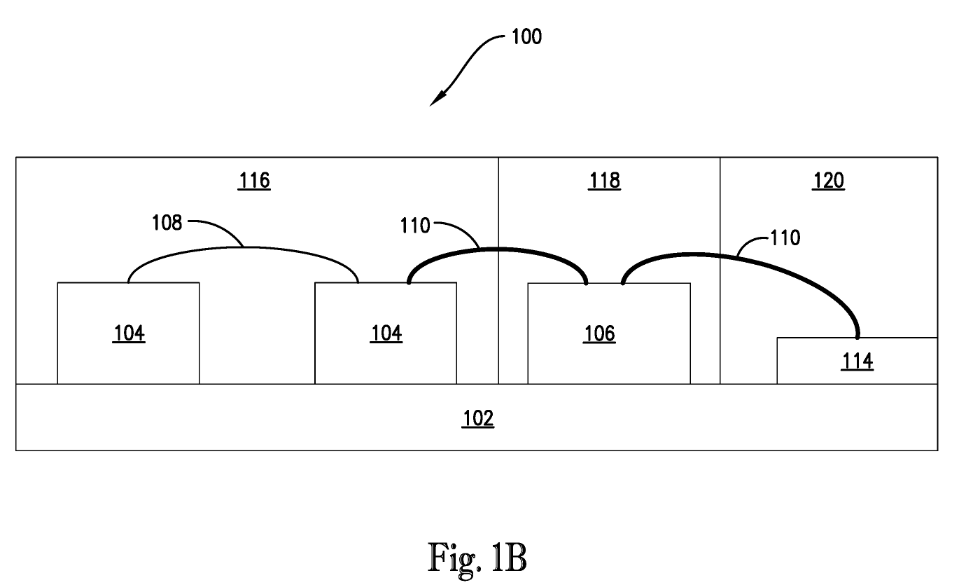

FIG. 1A illustrates a power module 100. The module 100 includes a substrate 102. A plurality of semiconductor dies may be disposed on the substrate 102. The semiconductor dies may include a first die subset 104 and a second die subset 106.

The dies 104, 106 may comprise, for example, metal–oxide–semiconductor field‑effect transistor (MOSFET) dies, insulated gate bipolar transistor (IGBT) dies, and/or diode dies. The dies may be fabricated in silicon, silicon carbide (SiC), gallium nitride (GaN), or other semiconductor materials.

In various examples, the first die subset 104 may operate at normal or lower temperatures during typical module operation. The second die subset 106 may be associated with one or more localized hot spot(s) and may exhibit higher operating temperatures relative to the dies 104.

In various examples, the dies 104, 106 may be mechanically and electrically secured to the substrate 102 using conventional die‑attach techniques. The attachment may be accomplished by soldering, sintering, or conductive adhesive bonding using epoxy or polyimide‑based materials. A die‑attach layer (not shown) may provide a thermally conductive path to the substrate while maintaining electrical contact and mechanical integrity throughout the operating temperature range.

A plurality of wires including a first wire subset 108 and a second wire subset 110 may connect respective ones of the dies to each other. The first wire subset 108 may provide electrical connections to components and dies that are not associated with the hot spot(s). For example, one or more wires of the first wire subset 108 may connect two (2) of the dies 104 together. The second wire subset 110 may be connected to respective dies of the second die subset 106. For example, one or more wires of the second wire subset 110 may connect one of the dies 106 to one of the dies 104 or other components of the module 100 (as will be described). The second wire subset 110 may be associated with a higher operating temperature than the first write subset 108.

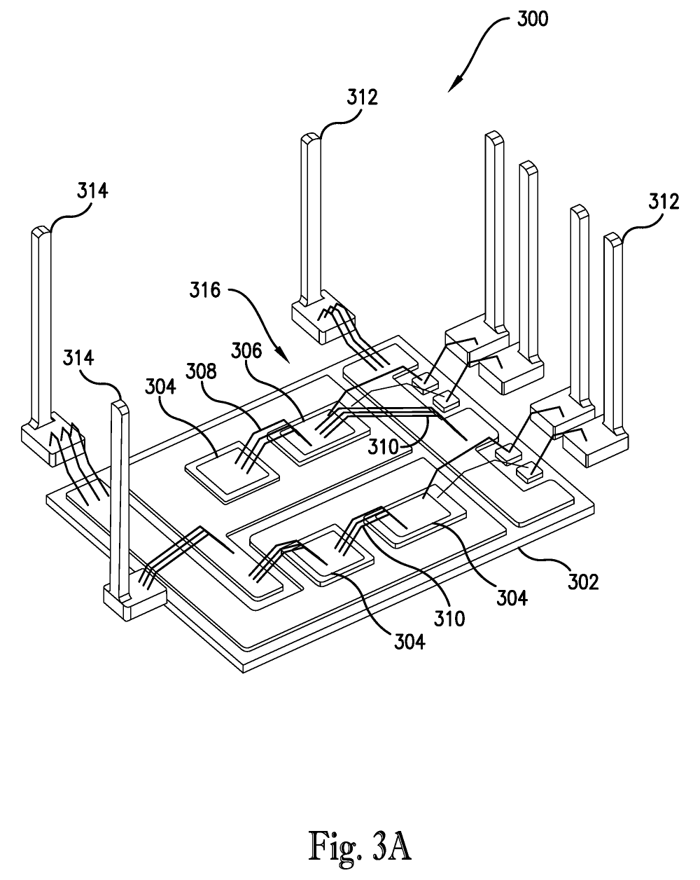

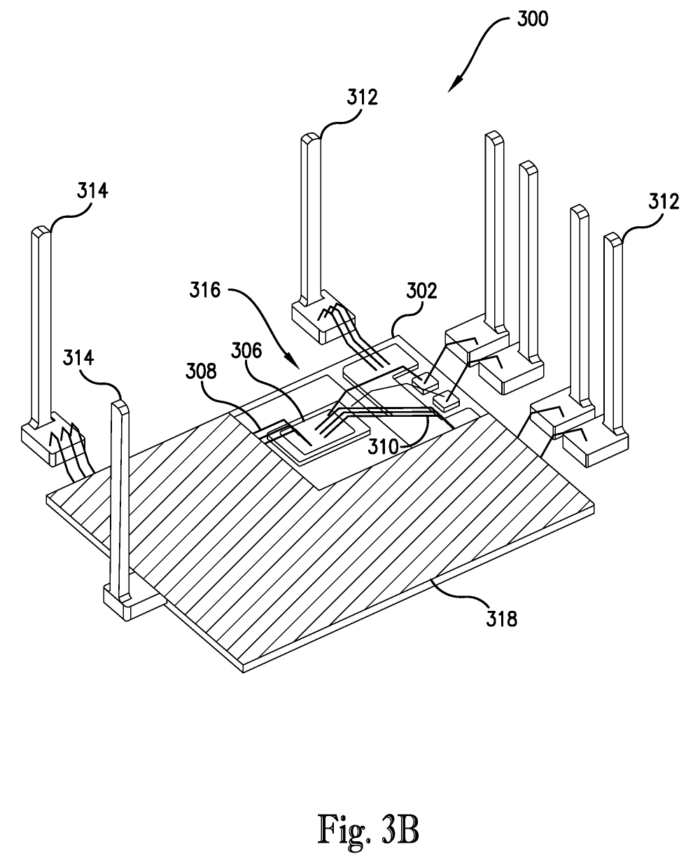

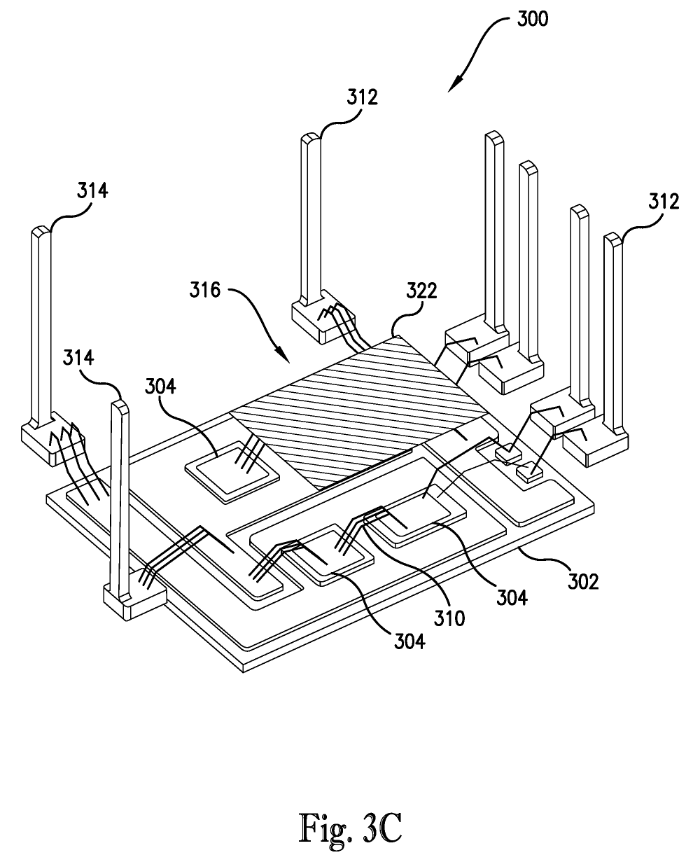

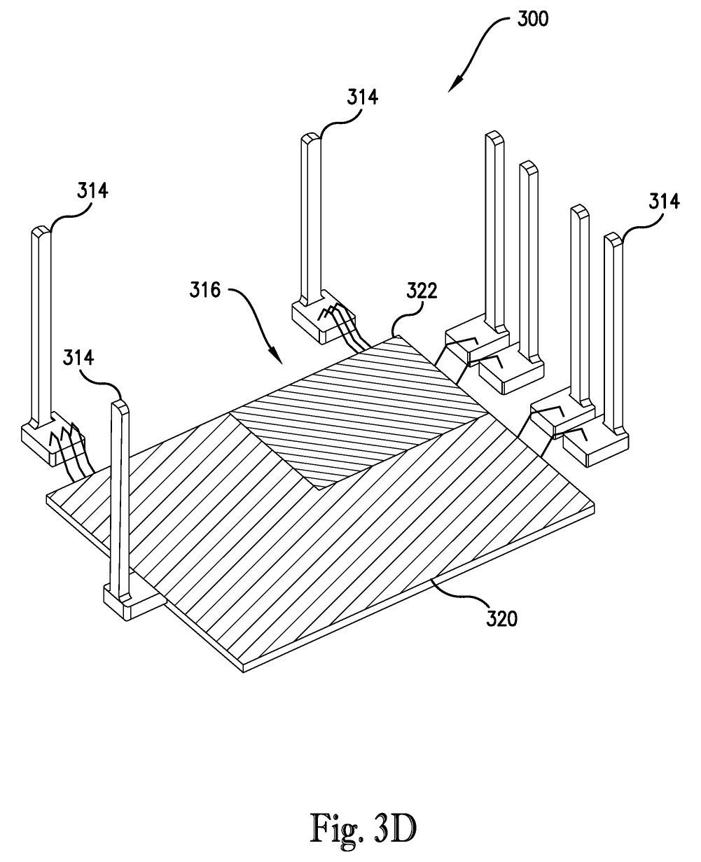

Terminals 112 and 114 may be located at an edge region of the substrate 102 and serve as external connection points. At least a portion of the terminals 112, 114 may be located adjacent the substrate 102. For example, the terminals 112, 114 may include a die connection portion located on the substrate 102 and an external connection portion extending from the substrate 102 (e.g., as shown in FIGS. 3A-3D). In various examples, the terminals 112, 114 may be described as terminal subsets, with terminal 112 forming a first terminal subset and terminal 114 forming a second terminal subset. Respective wires (e.g., one or more wires) from the first wire subset 108 may connect the terminal 112 to one or more of the dies 104. The terminal 114 may be associated with the hot spot(s). Accordingly, respective wires (e.g., one or more wires) of the second wire subset 110 may connect the terminal 114 to one or more of the dies 106.

To mitigate self-heating and resistive losses at the hotter interconnects, the wires of the second wire subset 110 are formed with greater thickness than the wires of the first wire subset 108. For example, the wires of the second wire subset 110 may be at least twenty percent (20%), at least thirty percent (30%), at least forty percent (40%), at least fifty percent (50%), or at least seventy five percent (75%) thicker than the wires of the first wire subset 108.

FIG. 1B is a cross-sectional elevation view taken along line 1B-1B of FIG. 1A. A first encapsulation material 116 is disposed over the first die subset 104. A second encapsulation material 118 is disposed over the second die subset 106. The second encapsulation material 118 has higher thermal conductivity than the first encapsulation material 116 to enhance heat spreading at localized hot spots associated with the second die subset 106. By way of example, the second encapsulation material 118 may comprise thermally enhanced epoxy or polyimide potting compounds loaded with ceramic fillers such as aluminum nitride (AlN), boron nitride (BN), or alumina (Al₂O₃), or a thermally conductive silicone or gel formulated with such fillers, each providing substantially greater thermal conductivity than standard silicone gel. The first encapsulation material 116 may comprise silicone gel.

An additional encapsulation material 120 is provided adjacent the terminal 114. The encapsulation material 120 may be formed of the same material as either the first encapsulation material 116 or the second encapsulation material 118, allowing selective use of either lower or higher thermal conductivity encapsulants near the terminal 114 according to design requirements.

During operation, the encapsulation material 118 and the second wire subset 110 may maintain the operating temperatures of the power module hot spots within a threshold range of the operating temperatures of the other locations of the power module 100, which may principally be due to heat dissipation to other, lower temperature portions of the module 100. The threshold range may be, for example, ten degrees Celsius (10º C) or less, without limitation. For example, if the dies 104 operate at a temperature of one hundred fifty degrees Celsius (150º C), the encapsulation material 118 and/or the second wire subset 110 may reduce the temperature of the dies 106 to around one hundred sixty degrees Celsius (160º C) or less. Accordingly, encapsulation material 118 and/or the second wire subset 110 may prevent overheating of the power module 100 and may extend the lifetime of the power module 100 by avoiding destructive effects of overheating.

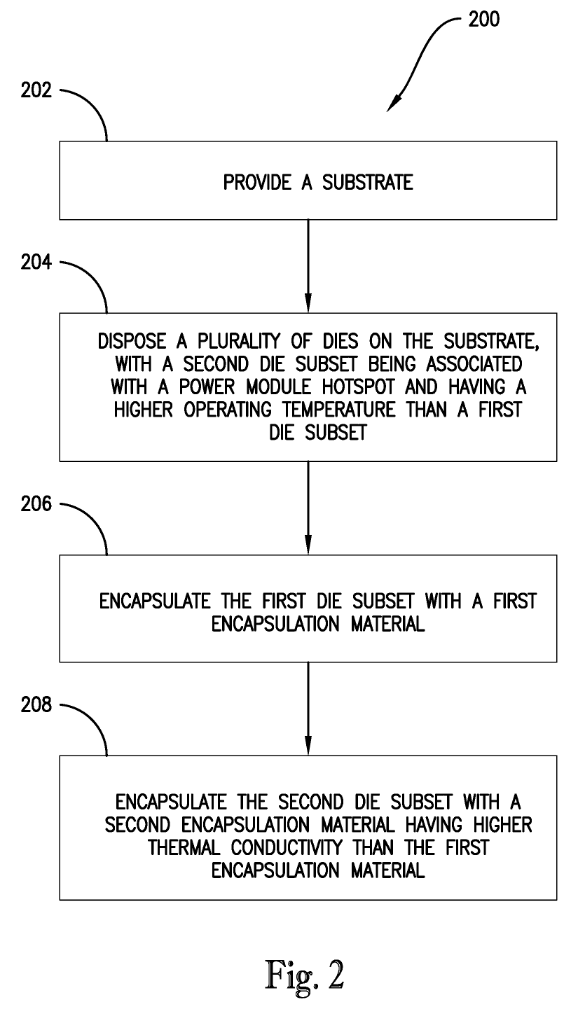

Referring to FIG. 2, an example method 200 of making a power module, such as the power module 100 described above, may include the operations set forth below. Referring additionally to FIGS. 3A–3D, example results of various operations are shown.

Referring to operation 202, a substrate 302 is provided (e.g., as seen in FIG. 3A). The substrate may comprise a direct bonded copper (DBC) substrate on a ceramic material, such as alumina (Al₂O₃), aluminum nitride (AlN), or silicon nitride (Si₃N₄), with copper metallization for heat spreading and current carrying, although it is within the ambit of the present disclosure that other substrate types (e.g., insulated metal substrates, thick-film substrates, and the like) may be utilized.

Referring to operation 204, a plurality of dies may be secured to the substrate 302. The dies include a first die subset 304 and a second die subset 306. Deposition of the dies 304, 306 on the substrate 302 may include mechanically and electrically securing the dies 304, 306 to the substrate 302 using a die-attach layer (not shown) formed by soldering, sintering, or conductive adhesive bonding. Each of the dies 304, 306 may include one or more transistors, diodes, or IC chips, as described above. The second die subset 306 may be associated with a localized hot spot region 316 and may exhibit a higher operating temperature than the first die subset 304 during typical module operation.

In various examples, after securing the dies 304, 306 on the substrate 302, wires may be bonded to respective ones of the dies 304, 306 and to first and second terminal subsets 312, 314. The terminal subsets 312, 314 may be located adjacent the substrate 302 and may provide external electrical connections to the power module 300. A first wire subset 308 may be connected to the dies 304 (e.g., components that are not associated with the hot spot region 316) and to the first terminal subset 312. A second wire subset 310 may be connected to the dies 306 and to the second terminal subset 314, as illustrated in FIGS. 3A–3D, where the second terminal subset 314 is associated with higher operating temperatures than the first terminal subset 312.

The second wire subset 310 may operate at higher temperatures than the first wire subset 308. Accordingly, the wires of the second wire subset 310 may be selected with greater thickness than the wires of the first wire subset 308 (e.g., as described above in connection with the wire subsets 108, 110).

Referring to operation 206, the first die subset 304 may be encapsulated with a first encapsulation material 320. The first encapsulation material 320 may comprise silicone gel.

Referring to operation 208, the second die subset 306 may be encapsulated with a second encapsulation material 322. The second encapsulation material 322 may have higher thermal conductivity than the first encapsulation material 320 (e.g., as described above in connection with the encapsulation materials 116 and 118). In one implementation, a mask 318 may be positioned to cover the first die subset 304, as shown in FIG. 3B. The mask 318 may present a gap that exposes the hot spot region 316, such that the second encapsulation material 322 is applied only over the hot spot region 316.

In various examples the second encapsulation material 322 may be dispensed after the first encapsulation material 320. The second encapsulation material 322 may be dispensed over the hot spot region 316 after positioning the mask 318 over the first die subset 304. The mask 318 may be removed after dispensing the second encapsulation material 322. The first encapsulation material 320 may be dispensed after removing the mask 318. If necessary, a mask or other suitable covering (not shown) may be provided over the second encapsulation material 322 while the first encapsulation material 320 is applied.

In accordance with various examples of the present disclosure, a power module may comprise a plurality of dies including a first die subset and a second die subset, with each subset including one or more of the dies. The second die subset may be associated with a power module hotspot such that the second die subset is associated with a higher operating temperature than the first die subset. A first encapsulation material may be disposed on the first die subset. A second encapsulation material may be disposed on the second die subset. The second encapsulation material may have higher thermal conductivity than the first encapsulation material.

In accordance with various examples of the present disclosure, a method of making a power module may comprise: providing a substrate; disposing a plurality of dies on the substrate, with a second die subset being associated with a power module hotspot and having a higher operating temperature than a first die subset; encapsulating the first die subset with a first encapsulation material; and encapsulating the second die subset with a second encapsulation material having higher thermal conductivity than the first encapsulation material.

The preceding examples may include any one or more of the following features.

The first encapsulation material may comprise silicone gel.

The power module may further comprise a plurality of wires including a first wire subset and a second wire subset, with each of the wire subsets including one or more of the wires. The wires may connect to respective dies. The second wire subset may operate at a higher temperature than the first wire subset. The second wire subset may have a greater wire thickness than the first wire subset.

The second wire subset may connect to the second die subset.

The power module may further comprise a plurality of terminals including a first terminal subset and a second terminal subset, with each of the terminal subsets including one or more of the terminals. The second terminal subset may be associated with the power module hotspot.

The power module may further comprise a substrate. The plurality of dies may be disposed on the substrate. The terminals may be adjacent the substrate.

At least one of the wires of the second wire subset may connect a respective one of the dies of the second die subset and a respective one of the terminals of the second terminal subset.

The second encapsulation material may be dispensed before the first encapsulation material.

Encapsulating the second die subset may include: placing a mask over the first die subset; providing the second encapsulation material over the second die subset; and removing the mask.

The method may further comprise connecting wires to respective dies, wherein a second wire subset operates at a higher temperature than a first wire subset; and selecting a greater wire thickness for the second wire subset than the first wire subset.

The method may further comprise connecting the second wire subset to the second die subset.

### General Considerations

While the present disclosure has been described herein with respect to certain illustrated examples, those of ordinary skill in the art will recognize and appreciate that the present disclosure is not so limited. Rather, many additions, deletions, and modifications to the illustrated and described examples may be made without departing from the scope of the disclosure as hereinafter claimed along with their legal equivalents. In addition, features from one example may be combined with features of another example while still being encompassed within the scope of the disclosure as contemplated by the inventors.

In this description, references to “one embodiment,” “an embodiment,” “embodiments,” “an example,” “one example,” or “examples” mean that the feature or features being referred to are included in at least one embodiment or example of the technology. Separate references to “one embodiment,” “an embodiment,” “embodiments,” “an example,” “one example,” or “examples” in this description do not necessarily refer to the same embodiment or example and are also not mutually exclusive unless so stated and/or except as will be readily apparent to those skilled in the art from the description. For example, a feature, structure, act, etc. described in one embodiment may also be included in other embodiments but is not necessarily included. Thus, the current technology can include a variety of combinations and/or integrations of the embodiments described herein.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein, unless otherwise expressly stated or as may be readily apparent to those skilled in the art.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

The patent claims at the end of this patent application are not intended to be construed under 35 U.S.C. § 112(f) unless traditional means-plus-function language is expressly recited, such as “means for” or “step for” language being explicitly recited in the claim(s).

What is claimed is:

1. A power module comprising:
a plurality of dies including a first die subset and a second die subset, with each of the die subsets including one or more of the dies,
the second die subset being associated with a power module hotspot, such that the second die subset is associated with a higher operating temperature than the first die subset;
a first encapsulation material disposed on first die subset; and
a second encapsulation material disposed on the second die subset,
the second encapsulation material having higher thermal conductivity than the first encapsulation material.

2. The power module of claim 1, comprising:
a plurality of wires including a first wire subset and a second wire subset, with each of the wire subsets including one or more of the wires,
the wires connecting to respective dies,
the second wire subset operating at a higher temperature than the first wire subset,
the second wire subset having a greater wire thickness than the first wire subset.

3. The power module of claim 2,
the second wire subset connecting to the second die subset.

4. The power module of claim 3,
the first encapsulation material comprising silicone gel.

5. The power module of claim 1,
the first encapsulation material comprising silicone gel.

6. The power module of claim 1, comprising:
a plurality of terminals including a first terminal subset and a second terminal subset, with each of the terminal subsets including one or more of the terminals,
the second terminal subset being associated with the power module hotspot.

7. The power module of claim 6, comprising:
a plurality of wires including a first wire subset and a second wire subset, with each of the wire subsets including one or more of the wires,
the wires connecting to respective dies,
the second wire subset operating at a higher temperature than the first wire subset,
the second wire subset having a greater wire thickness than the first wire subset .

8. The power module of claim 7,
at least one of the wires of the second wire subset connecting a respective one of the dies of the second die subset and a respective one of the terminals of the second terminal subset.

9. The power module of claim 7,
the second wire subset connecting to the second die subset.

10. The power module of claim 7,
the first encapsulation material comprising silicone gel.

11. The power module of claim 1, comprising:
a substrate,
the plurality of dies being disposed on the substrate; and
a plurality of terminals including a first terminal subset and a second terminal subset, with each of the terminal subsets including one or more of the terminals,
the terminals being adjacent the substrate,
the second terminal subset being associated with the power module hotspot.

12. The power module of claim 11, comprising:
a plurality of wires including a first wire subset and a second wire subset, with each of the wire subsets including one or more of the wires,
the wires connecting to respective dies,
the second wire subset operating at a higher temperature than the first wire subset,
the second wire subset having a greater wire thickness than the first wire subset .

13. The power module of claim 12,
at least one of the wires of the second wire subset connecting a respective one of the dies of the second die subset and a respective one of the terminals of the second terminal subset.

14. The power module of claim 12,
the second wire subset connecting to the second die subset.

15. The power module of claim 12,
the first encapsulation material comprising silicone gel.

16. A method of making a power module comprising:
providing a substrate;
disposing a plurality of dies on the substrate, with a second die subset being associated with a power module hotspot and having a higher operating temperature than a first die subset;
encapsulating the first die subset with a first encapsulation material; and
encapsulating the second die subset with a second encapsulation material having higher thermal conductivity than the first encapsulation material.

17. The method of claim 16, wherein the second encapsulation material is dispensed before the first encapsulation material.

18. The method of claim 17, wherein encapsulating the second die subset includes:
placing a mask over the first die subset,
providing the second encapsulation material over the second die subset, and
removing the mask.

19. The method of claim 16, comprising:
connecting wires to respective dies, wherein a second wire subset operates at a higher temperature than a first wire subset; and
selecting a greater wire thickness for the second wire subset than the first wire subset.

20. The method of claim 19, comprising:
connecting the second wire subset to the second die subset.
